(19) United States
(12) Patent Application Publication
(10) Pub. No.: US 2024/0035197 A1
(43) Pub. Date: Feb. 1, 2024

(54) Crystal Puller, Method for Manufacturing Monocrystalline Silicon Ingots and Monocrystalline Silicon Ingots

(71) Applicant: XI’AN ESWIN MATERIAL TECHNOLOGY CO., LTD., Xi'an (CN)

(72) Inventors: Wanwan ZHANG, Xi'an (CN); Yonghee MUN, Xi'an (CN)

(21) Appl. No.: 18/258,769

(22) PCT Filed: Sep. 29, 2022
(86) PCT No.: PCT/CN2022/122594

§ 371 Date: Jun. 21, 2023

(30) Foreign Application Priority Data
Sep. 30, 2021 (CN) 202111165968.6

(51) Int. Cl. C30B 29/06; C30B 15/20; C30B 33/02

(52) U.S. Cl. CPC C30B 29/06; C30B 15/20; C30B 33/02

(57) ABSTRACT

The present disclosure discloses a crystal puller, a method for manufacturing a monocrystalline silicon ingot and a mono-crystalline silicon ingot. The crystal puller includes a pulling mechanism; a first heat treater which is configured to perform heat treatment on the mono-crystalline silicon ingot with a first heat treatment temperature at which BMD in the mono-crystalline silicon ingot be ablated; and a second heat treater which is configured to perform heat treatment on the monocrystalline silicon ingot with a second heat treatment temperature at which formation of BMD in the mono-crystalline silicon ingot is induced. The pulling mechanism is further configured to move the monocrystalline ingot along the direction of crystal growth to a position where heat treatment is performed on a tail section by the first heat treater and heat treatment is performed on a head section by the second heat treater.

### CROSS-REFERENCE TO RELATED APPLICATIONS

This disclosure claims a priority to Chinese Patent Application No. 202111165968.6 filed on Sep. 30, 2021, the disclosures of which are incorporated in their entirety by reference herein.

### TECHNICAL FIELD

The present disclosure relate to the field of semiconductor wafer production, and in particular to a crystal puller, a method for manufacturing monocrystalline silicon ingots and the monocrystalline silicon ingots obtained by the method.

### BACKGROUND

It is well known that modern integrated circuits are mainly manufactured on the near-surface layer within 5 microns of the silicon wafer surface. Therefore, techniques such as intrinsic or extrinsic getter are required in order to form a defect zone in the body or back surface of the silicon wafer and form a denuded zone within a depth of 10 um to 20 μm from the near surface, which is free of defects and impurities. In recent years, in addition to conventional intrinsic and extrinsic getter techniques, new oxygen annealing techniques, rapid heat treatment techniques and nitrogen doping techniques have been developed and applied.

In the above-mentioned integrated circuits, it is advantageous to provide such a silicon wafer that has a denuded zone (DZ) extending inwardly into the body from the front surface and a bulk micro defect (BMD) zone adjacent to the DZ and further extending into the body. The front surface refers to a surface of the silicon wafer on which electronic components are to be formed. The above-mentioned DZ is important for the following reasons: in order to form electronic components on a silicon wafer, it is required that there is no crystal defect in the area for forming the electronic components, otherwise it will lead to circuit breakage and other faults. Thus, the electronic components can be formed in the DZ to avoid the influence of crystal defects. The effect of the above-mentioned BMD is that it can produce an Intrinsic Getter (IG) effect on metal impurities to keep metal impurities in the part of the silicon wafers away from the DZ. Thus, the adverse effects such as the increase of leakage current and the reduction of gate oxide film quality caused by metal impurities can be avoided.

In the process of producing the above-mentioned silicon wafers with BMD zones, it is very advantageous to dope with nitrogen in the silicon wafers. For example, in the case of a silicon wafer doped with nitrogen, the nitrogen atoms firstly combine with each other at high temperatures to form diatomic nitrogen, which promotes the formation of oxygen precipitation, and consumes a large number of vacancies, thereby making the concentration of vacancies reduce. Because VOID defects are composed of vacancies, the reduction in vacancy concentration leads to a reduction in the size of VOID defects, resulting in the formation of silicon wafers with reduced size of VOID defect at relatively low temperatures. In the high-temperature heat treatment of the integrated circuits manufacturing process, the VOID defects of the nitrogen-doped monocrystalline silicon are easily eliminated, thus improving the yield of the integrated circuits. At the same time, doping with nitrogen can promote the formation of a BMD with nitrogen as the core, so that the BMD can reach a certain concentration and make the BMD effectively play a role as a source for absorbing metal impurities. Moreover, it is also possible to have a favorable effect on the concentration distribution of the BMD, for example, making the concentration of the BMD more evenly distributed in the radial direction of the silicon wafer; for another example, making the concentration of the BMD is higher in the zone adjacent to the DZ and gradually decreasing toward the body of silicon wafer, etc.

In related technologies, silicon wafers used for producing above semiconductor electronic components, such as integrated circuits, are mainly produced by slicing monocrystalline silicon ingots pulled by a Czochralski method. The Czochralski method includes melting polycrystalline silicon in a quartz crucible to obtain a silicon melt, immersing a monocrystalline seed into the silicon melt, and continuously pulling the seed to move away from the surface of the silicon melt, thereby a monocrystalline silicon ingot is grown at the phases interface during pulling. Pulling monocrystalline silicon ingots by the Czochralski method is generally preformed in a crystal puller. Due to the mismatch between the lattice of a dopant element and the lattice of the silicon element, there is a segregation phenomenon during growing of monocrystalline silicon, i.e. the concentration of the dopant element crystallized in the monocrystalline silicon ingot is less than that in the melt (feedstock), which makes the concentration of the dopant element in the crucible increase and the concentration of the dopant element in the monocrystalline silicon ingots also increase. Since the segregation coefficient of nitrogen in the monocrystalline silicon ingots is small, only 7×10⁻⁴, the distribution of nitrogen concentration is as gradually increasing from the head to the tail of the monocrystalline silicon ingot during pulling monocrystalline silicon ingots. As shown in FIG. 1, it illustrates the theoretical distribution of nitrogen concentration along the crystal growth direction in the monocrystalline silicon ingot doped with nitrogen. The nitrogen concentrations in the head and in the tail of the monocrystalline silicon ingot doped with nitrogen are significantly different, and accordingly it results in a large difference between the BMD concentrations in the head and in the tail of the monocrystalline silicon ingot doped with nitrogen.

### SUMMARY

To solve the above technical problems, embodiments of the present disclosure provide a crystal puller, a method for manufacturing a monocrystalline silicon ingot and the monocrystalline silicon ingot obtained by the method. The embodiments of the present disclosure can solve the problem of large differences in BMD concentration between in the head and in the tail of the monocrystalline silicon ingot due to excessive differences in the nitrogen concentration from the head to the tail of the monocrystalline silicon ingot during pulling monocrystalline silicon ingots, and provide a monocrystalline silicon ingot with an uniform BMD concentration.

The technical solutions of the present disclosure are as follows.

In first aspect, embodiments of the present disclosure provide a crystal puller for manufacturing a monocrystalline silicon ingot, the crystal puller comprising:
a pulling mechanism which is configured to pull the monocrystalline silicon ingot from a nitrogen-doped silicon melt by a Czochralski method;
a first heat treater which is configured to perform heat treatment on the mono-crystalline silicon ingot with a first heat treatment temperature at which bulk micro defects (BMD) in the monocrystalline silicon ingot are ablated; and
a second heat treater arranged on the first heat treater, which is configured to perform heat treatment on the mono-crystalline silicon ingot with a second heat treatment temperature at which formation of BMD in the mono-crystalline silicon ingot is induced;
in which the pulling mechanism is further configured to move the monocrystalline silicon ingot along the direction of crystal growth to a position where a tail section of the monocrystalline silicon ingot is heat treated by the first heat treater and a head section of the monocrystalline silicon ingot is heat treated by the second heat treater.

Optionally, the first heat treatment temperature is in a range from 950 degrees Celsius to 1200 degrees Celsius.

Optionally, the second heat treatment temperature is in a range from 600 degrees Celsius to 850 degrees Celsius.

Optionally, the crystal puller further comprising:
a first temperature sensor for sensing the heat treatment temperature of the first heat treater;
a second temperature sensor for sensing the heat treatment temperature of the second heat treater; and
a controller which is configured to control the first heat treater and the second heat treater to provide different heat treatment temperatures respectively as a function of the temperatures sensed by the first temperature sensor and the second temperature sensor.

Optionally, the second heat treater comprises a first segment and a second segment arranged along the direction of crystal growth, the first segment providing a heat treatment temperature of 600 degrees Celsius to 700 degrees Celsius and the second segment providing a heat treatment temperature of 700 degrees Celsius to 850 degrees Celsius.

Optionally, the pulling mechanism is further configured to allow the monocrystalline silicon ingot to stay for 2 hours at a position where the heat treatment is performed.

Optionally, the crystal puller comprises an upper puller chamber with a small radial dimension and a lower furnace chamber with a large radial dimension, the first heat treater and the second heat treater are arranged in the upper furnace chamber, and a crucible and a heater for heating the crucible are provided inside the lower furnace chamber.

Optionally, the total length of the first heat treater and the second heat treater along the direction of crystal growth is greater than or equal to the length of the monocrystalline silicon ingot, such that the entire monocrystalline silicon ingot is able to be heat-treated simultaneously by the first heat treater and the second heat treater.

In a second aspect, embodiments of the present disclosure provide a method for manufacturing a monocrystalline silicon ingot, the method comprising:
pulling a monocrystalline silicon ingot from a nitrogen-doped silicon melt by a Czochralski method;
moving the monocrystalline silicon ingot along the direction of crystal growth to a position where the monocrystalline silicon ingot is subjected to heat treatment;
performing heat treatment to a tail section of the monocrystalline silicon ingot with the first heat treatment temperature at which bulk micro defects (BMD) in the monocrystalline silicon ingot are ablated; and
preforming heat treatment on a head section of the mono-crystalline silicon ingot with the second heat treatment temperature at which formation of BMD in the mono-crystalline silicon ingot is induced.

In third aspect, embodiments of the present disclosure provide a monocrystalline silicon ingot which is manufactured by the method according to the second aspect.

### BRIEF DESCRIPTION OF THE DRAWINGS

FIG. 1 is a schematic diagram of the theoretical distribution of nitrogen concentration in nitrogen-doped monocrystalline silicon ingot along the crystal growth direction in related technology;

FIG. 2 is a schematic diagram of an embodiment of a conventional crystal puller;

FIG. 3 is a schematic diagram of a crystal puller according to an embodiment of the present disclosure which illustrates a monocrystalline silicon ingot being pulled from a silicon melt;

FIG. 4 is another schematic diagram of the crystal puller of FIG. 3 which illustrates the monocrystalline silicon ingot has been completely pulled from the silicon melt and is in the first heat treater and the second heat treater;

FIG. 5 is a schematic diagram of a crystal puller according to another embodiment of the present disclosure;

FIG. 6 is a schematic diagram of a crystal puller according to another embodiment of the present disclosure;

FIG. 7 is a schematic diagram of a method for manufacturing the monocrystalline silicon ingot according to an embodiment of the present disclosure.

### DETAILED DESCRIPTION

The technical solutions according to embodiments of the present disclosure will be described hereinafter in conjunction with the drawings in the embodiments of the present disclosure in a clear and complete manner.

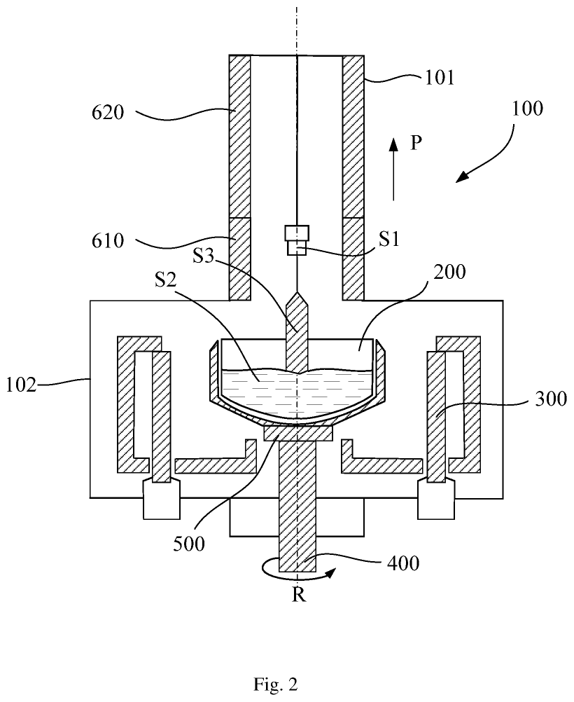

Referring to FIG. 2, it shows an embodiment of a conventional crystal puller. The crystal puller 100 comprises an upper puller chamber 101 with a small radial dimension and a lower puller chamber 102 with a large radial dimension. The lower puller chamber 102 is provided with a crucible 200, which may specifically include a graphite crucible and a quartz crucible. The crucible 200 is configured to hold silicon material, and a heater 300 is arranged between the inner wall of the lower puller chamber and the outer circumference of the crucible. The heater 300 is configured to heat the crucible and the silicon material within it to form a silicon melt S2. A pulling channel is arranged at the top of the lower puller chamber 102, the pulling channel is connected to the upper puller chamber 101, where the monocrystalline silicon ingot S3 is pulled. In addition, a crucible rotation mechanism 400 and a crucible supporter 500 are arranged in the lower puller chamber 102. The crucible 200 is supported by the crucible supporter 500, and the crucible rotating mechanism 400 is located below the crucible supporter 500 for driving the crucible 200 to rotate around its own axis along the direction R.

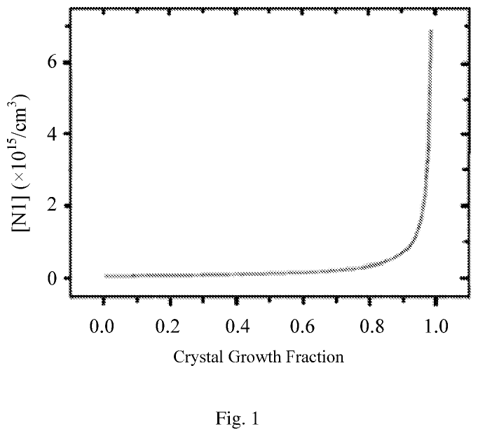

When using the crystal puller 100 to pull a monocrystalline silicon ingot S3, firstly, high purity polycrystalline silicon feedstock is placed into the crucible 200 and the crucible 200 is continuously heated by the heater 300 while the crucible rotation mechanism 400 drives the crucible 200 to rotate, so that the polycrystalline silicon feedstock housed in the crucible is melted into a molten state, i.e., melting into the silicon melt S2. The heating temperature is maintained at about one thousand degrees Celsius. The gas filled in the puller is usually an inert gas that allows the polycrystalline silicon to melt without creating unnecessary chemical reactions at the same time. When the liquid surface temperature of the silicon melt S2 is controlled at the critical point of crystallization by controlling the hot zone provided by the heater 300, by lifting the monocrystalline seed S1, located on the liquid surface, upward from the liquid surface along the direction P, the silicon melt S2 grows into the monocrystalline silicon ingot S3 in the crystal direction of the monocrystalline seed S1 as the monocrystalline seed S1 is lifted upward. In order to make finally produced silicon wafers have high BMD concentration, monocrystalline silicon ingot may be doped with nitrogen during pulling monocrystalline silicon ingot, for example nitrogen gas may be filled into the puller chamber of the crystal puller 100 during pulling or may dope the silicon melt S2 in the crucible 200 with nitrogen, so that the pulled monocrystalline silicon ingot and the silicon wafers slicing from the monocrystalline silicon ingot will be doped with nitrogen. However, referring to the FIG. 1, the N concentration in the tail section of the monocrystalline silicon ingot manufactured by the crystal puller 100 is higher, and the N concentration in the head section is lower. This results in a low BMD concentration in the head section and a high BMD concentration in the tail section of the monocrystalline silicon ingots, which leads to a decrease in the quality and yield of the monocrystalline silicon ingots.

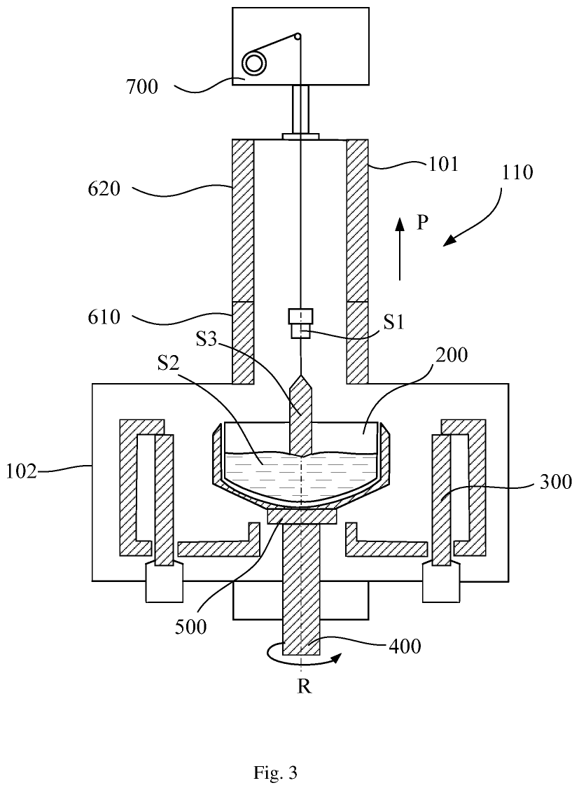

In order to solve the problem of uneven overall BMD concentration of the monocrystalline silicon ingot, the present disclosure provides a crystal puller 110, refers to FIG. 3, the crystal puller 110 comprises: a pulling mechanism 700, which is configured to pull the monocrystalline silicon ingot S3 from a nitrogen-doped silicon melt S2 by a Czochralski method; a first heat treater 610 and a second heat treater 620 arranged above the first heat treater 610, both the first heat treater 610 and the second heat treater 620 are arranged in the above-mentioned upper puller chamber 101 and stacked vertically along the direction of crystal growth P. The first heat treater 610 is configured to preform heat treatment on the monocrystalline silicon ingot S3 with the first heat treatment temperature at which BMD in the monocrystalline silicon ingot S3 are ablated. The second heat treater 620 is configured to preform heat treatment on the monocrystalline silicon ingot S3 with the second heat treatment temperature at which formation of BMD in the monocrystalline silicon ingot S3 is induced. The pulling mechanism 700 is further configured to move the monocrystalline ingot S3 along the direction of crystal growth to a position where a tail section is performed heat treatment by the first heat treater 610 and a head section is performed heat treatment by the second heat treater 620.

The first heat treater 610 provides a first heat treatment temperature of 950 to 1200 degrees Celsius, providing a lower temperature zone in the range of 950 to 1200 degrees Celsius to the section of monocrystalline silicon ingot located in the first heat treater 610. When the section of monocrystalline silicon ingot S3 with high nitrogen content is heat treated in the lower temperature zone, the BMD in this section will be ablated at this temperature, thereby achieving a reduction of the BMD concentration in this section. The second heat treater 620 provides a second heat treatment temperature of 600 to 850 degrees Celsius, providing an upper temperature zone in the range of 600 to 700 degrees Celsius to the section of monocrystalline silicon ingot located in the second heat treater. When the section of monocrystalline silicon ingot S3 with low nitrogen content is heat treated in the lower temperature zone, it facilitates the BMD nucleation in this section, thereby achieving an increased BMD concentration in this section. This allows the sections with inconsistent BMD concentration in the monocrystalline silicon ingot to be subjected corresponding heat treatment at different heat treatment temperatures, thereby avoiding an uneven overall BMD concentration in the monocrystalline silicon ingot.

Referring to FIG. 1, the BMD concentration in the head section of the monocrystalline silicon ingot located in the upper temperature zone is small. Optionally, the second heat treater comprises a first segment and a second segment arranged vertically along the direction of crystal growth P. The first segment is configured to provide heat treatment temperatures from 600 degrees Celsius to 700 degrees Celsius, and the second segment is configured to provide heat treatment temperatures from 700 degrees Celsius to 850 degrees Celsius. The first segment and the second segment were used for performing heat treatment at different temperatures for the sections with different BMD concentrations in the monocrystalline ingot S3, it ensures more sufficient BMD nucleation and obtains monocrystalline ingot S3 with a more uniform BMD concentration.

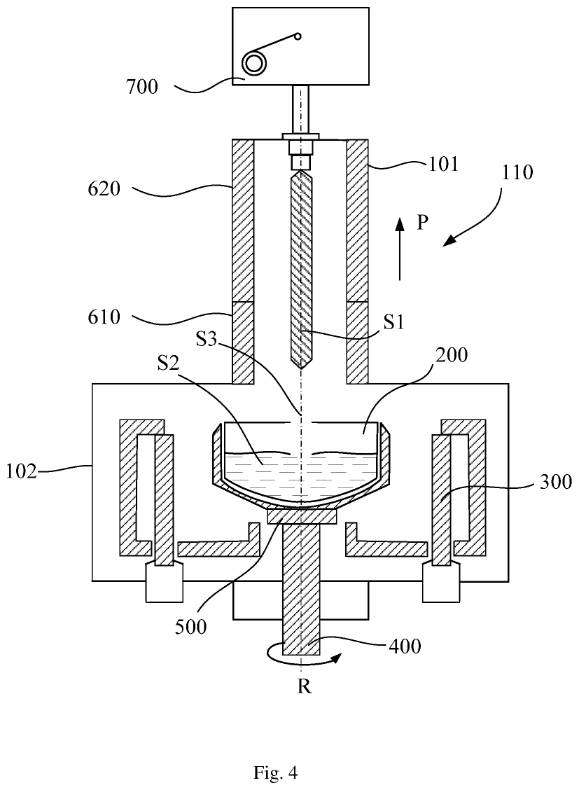

Referring to FIG. 4, the pulling mechanism 700 is configured to move the monocrystalline ingot S3 along the direction of crystal growth so that the monocrystalline ingot S3 grows from the phases interface located in the lower puller chamber 102 and moves to a position where the heat treatment is performed by the first heat treater 610 and the second heat treater 620. In order to enable the monocrystalline silicon ingot S3 to experience the heat treatment under predetermined conditions, optionally, the pulling mechanism 700 is configured to allow the overall mono-crystalline silicon ingot S3 to stay in the first heat treater 610 and the second heat treater 620 for the heat treatment time required. As shown in FIG. 4, the monocrystalline silicon ingot S3 has been pulled by the pulling mechanism 700 to completely locate in the first heat treater 610 and the second heat treater 620, and the pulling mechanism 700 enable the monocrystalline silicon ingot S3 to stay in that position until a predetermined heat treatment time has been experienced.

In optional embodiments of the present disclosure, the heat treatment time may be 2 hours.

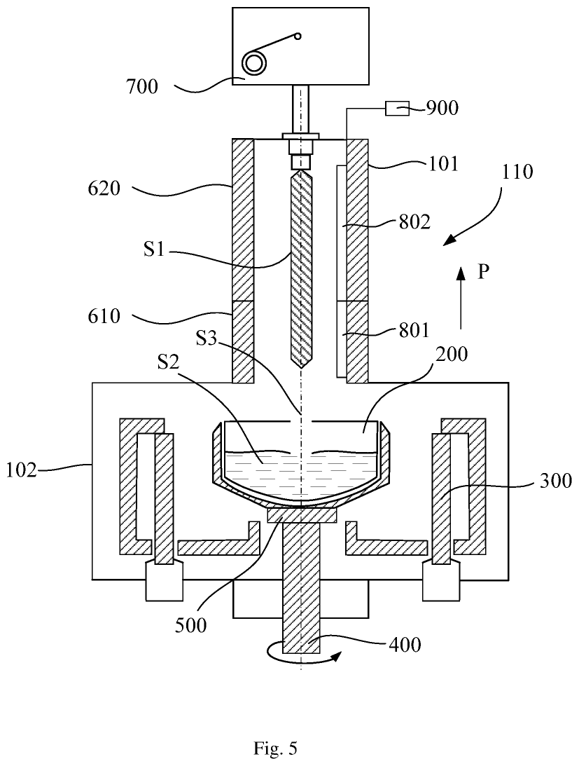

To further control the accuracy of the heat treatment temperature, optionally, referring FIG. 5, the crystal puller 110 further comprises a first temperature sensor 801 for sensing the heat treatment temperature of the first heat treater 610, a second temperature sensor 802 for sensing the heat treatment temperature of the second heat treater 620, and a controller 900 for controlling the first heat treater 610 and the second heat treater 620 according to the heat treatment temperatures sensed by the first temperature sensor 801 and the second temperature sensor 802. The first temperature sensor 801 is arranged on the side of the first heat treater 610 toward the inner surface of upper puller chamber 101, and the temperature of the lower temperature zone is measured by the sensing probe to obtain the heat treatment temperature of temperature zone where the different sections of the monocrystalline silicon ingot S3 are located. Subsequently, the heating power of the first heat treater 610 is controlled by the controller 900 electrically connected thereto, to accurately adjust the first heat treatment temperature and ensure the temperature of the lower temperature zone is constant. The second temperature sensor 802 is arranged on the side of the second heat treater 620 toward the inner surface of upper puller chamber 101, and its operating principle is consistent with that of the first temperature sensor 801, which will not be repeated here.

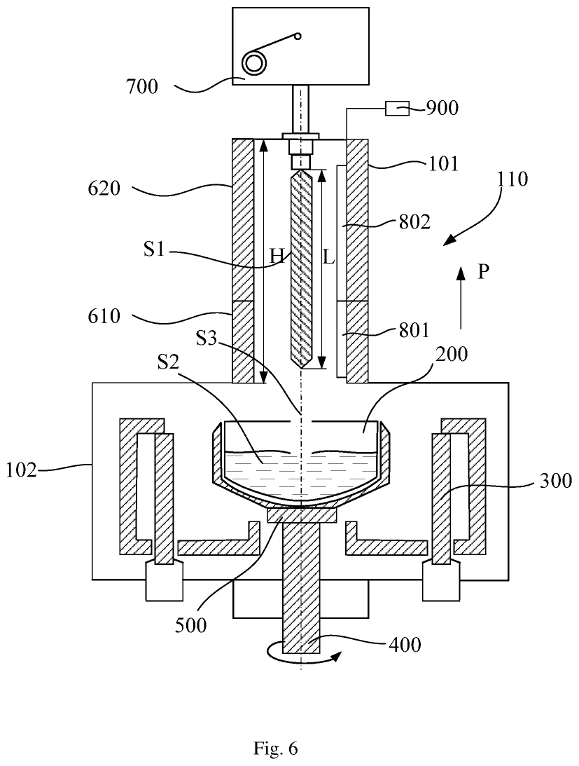

In one embodiment of the present disclosure, the crystal puller 110 is arranged so that the entire monocrystalline silicon rob S3 is simultaneously subjected to heat treatment in both the first heat treater and the second heat treater. In this regard, optionally, as shown in FIG. 6, the length H of the first heat treater 610 and the second heat treater 620 along the direction of crystal growth P is greater than or equal to the length L of the monocrystalline silicon rob S3 so that the monocrystalline silicon rob S3 can be fully located in the first heat treater 610 and the second heat treater 620, while different sections of the monocrystalline silicon rob S3 were heat treated correspondingly.

By using the crystal puller according to the embodiment of the present disclosure, the problem of uneven overall BMD concentration of monocrystalline silicon ingot due to the small N partition coefficient when pulling nitrogen-doped monocrystalline silicon ingot, which makes the N concentration at the head section of the monocrystalline silicon ingot much smaller than that at the tail section the crystal ingot, has been solved.

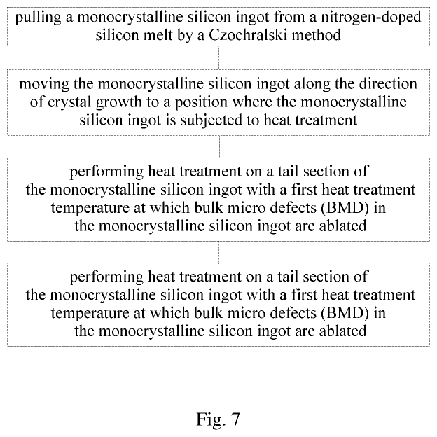

Referring to FIG. 7, embodiments of the present disclosure further provide a method for manufacturing monocrystalline silicon ingots, the method may comprising:
pulling a monocrystalline silicon ingot from a nitrogen-doped silicon melt by a Czochralski method;
moving the monocrystalline silicon ingot along the direction of crystal growth to a position where the monocrystalline silicon ingot is subjected to heat treatment;
performing heat treatment on a tail section of the monocrystalline silicon ingot with a first heat treatment temperature at which bulk micro defects (BMD) in the monocrystalline silicon ingot are ablated; and performing heat treatment on a head section of the monocrystalline silicon ingot with a second heat treatment temperature at which formation of BMD in the monocrystalline silicon ingot is induced.

Embodiments of the present disclosure further provide a monocrystalline silicon ingot, which is manufactured by the method for manufacturing a monocrystalline silicon ingot provided by the embodiments of the present disclosure.

It should be noted that the technical solutions described in the embodiments of this disclosure can be combined with each other in any way without conflict.

The above description is merely the specific embodiment of the present disclosure, but the scope of the present disclosure is not limited thereto. Moreover, any person skilled in the art would readily conceive of modifications or substitutions within the technical scope of the present disclosure, and these modifications or substitutions shall also fall within the protection scope of the present disclosure. Therefore, the protection scope of the present disclosure should be determined by the scope of the claims.

1. A crystal puller for manufacturing a monocrystalline silicon ingot comprising:
a pulling mechanism configured to pull the monocrystalline silicon ingot from a nitrogen-doped silicon melt by a Czochralski method;
a first heat treater which is configured to perform a first heat treatment on the monocrystalline silicon ingot with a first heat treatment temperature at which bulk micro defects (BMD) in the monocrystalline silicon ingot are ablated; and
a second heat treater arranged on the first heat treater, which is configured to perform a second heat treatment on the monocrystalline silicon ingot with a second heat treatment temperature at which formation of the BMD in the monocrystalline silicon ingot is induced,
wherein the pulling mechanism is further configured to move the monocrystalline ingot along the direction of crystal growth to a position where the first heat treatment is performed on a tail section of the monocrystalline ingot by the first heat treater and the second heat treatment is performed on a head section of the monocrystalline ingot by the second heat treater.

2. The crystal puller according to claim 1, wherein the first heat treatment temperature is in a range from 950 degrees Celsius to 1200 degrees Celsius.

3. The crystal puller according to claim 1, wherein the second heat treatment temperature is in a range from 600 degrees Celsius to 850 degrees Celsius.

4. The crystal puller according to claim 1, wherein the crystal puller further comprises:
a first temperature sensor for sensing the first heat treatment temperature of the first heat treater;
a second temperature sensor for sensing the second heat treatment temperature of the second heat treater; and
a controller which is configured to control the first heat treater and the second heat treater to provide different heat treatment temperatures respectively as a function of the temperatures sensed by the first temperature sensor and the second temperature sensor.

5. The crystal puller according to claim 4, wherein the second heat treater comprises a first segment for providing a first segment heat treatment temperature from 600 degrees Celsius to 700 degrees Celsius and a second segment for providing a second segment heat treatment temperature from 700 degrees Celsius to 850 degrees Celsius arranged along the direction of crystal growth.

6. The crystal puller according to claim 1, wherein the pulling mechanism is further configured to allow the monocrystalline silicon ingot to stay for 2 hours at a position where the heat treatment is performed.

7. The crystal puller according to claim 1, wherein the crystal puller comprises an upper puller chamber with a small radial dimension and a lower puller chamber with a large radial dimension, and wherein the first heat treater and the second heat treater are arranged in the upper puller chamber, and both a crucible and a heater for heating the crucible are provided inside the lower puller chamber.

8. The crystal puller according to claim 1, wherein a total length of the first heat treater and the second heat treater along the direction of crystal growth is greater than or equal to a length of the monocrystalline silicon ingot, such that the entire monocrystalline silicon ingot is able to be heat-treated simultaneously by the first heat treater and the second heat treater.

9. A method for manufacturing a monocrystalline silicon ingot which comprises:
pulling a monocrystalline silicon ingot from a nitrogen-doped silicon melt by a Czochralski method;
moving the monocrystalline silicon ingot along a direction of crystal growth to a position where the monocrystalline silicon ingot is subjected to heat treatment;
performing heat treatment on a tail section of the monocrystalline silicon ingot with a first heat treatment temperature at which bulk micro defects (BMD) in the monocrystalline silicon ingot are ablated; and
performing heat treatment on a head section of the monocrystalline silicon ingot with a second heat treatment temperature at which formation of the BMD in the monocrystalline silicon ingot is induced.

10. A monocrystalline silicon ingot which is manufactured by the method according to claim 9.

11. The crystal puller according to claim 2, wherein the crystal puller further comprises:
a first temperature sensor for sensing the first heat treatment temperature of the first heat treater;
a second temperature sensor for sensing the second heat treatment temperature of the second heat treater; and
a controller which is configured to control the first heat treater and the second heat treater to provide different heat treatment temperatures respectively as a function of the temperatures sensed by the first temperature sensor and the second temperature sensor.

12. The crystal puller according to claim 3, wherein the crystal puller further comprises:
a first temperature sensor for sensing the first heat treatment temperature of the first heat treater;
a second temperature sensor for sensing the second heat treatment temperature of the second heat treater; and
a controller which is configured to control the first heat treater and the second heat treater to provide different heat treatment temperatures respectively as a function of the temperatures sensed by the first temperature sensor and the second temperature sensor.

13. The crystal puller according to claim 2, wherein a total length of the first heat treater and the second heat treater along the direction of crystal pulling is greater than or equal to a length of the monocrystalline silicon ingot, such that the entire monocrystalline silicon ingot is able to be heat-treated simultaneously by the first heat treater and the second heat treater.

14. The crystal puller according to claim 3, wherein a total length of the first heat treater and the second heat treater along the direction of crystal pulling is greater than or equal to a length of the monocrystalline silicon ingot, such that the entire monocrystalline silicon ingot is able to be heat-treated simultaneously by the first heat treater and the second heat treater.
